(19) United States
(12) Patent Application Publication
(10) Pub. No.: US 2025/0042749 A1
(43) Pub. Date: Feb. 6, 2025

(54) COLLOIDAL SILICA AND PRODUCTION METHOD THEREFOR

(71) Applicant: FUSO CHEMICAL CO., LTD., Osaka-shi, Osaka (JP)

(72) Inventors: Chiharu Nakano, Fukuchiyama-shi, Kyoto (JP); Toshiki Chiba, Fukuchiyama-shi, Kyoto (JP); Yuma Kobayashi, Fukuchiyama-shi, Kyoto (JP); Takahiro Tashima, Fukuchiyama-shi, Kyoto (JP); Shuta Ozawa, Fukuchiyama-shi, Kyoto (JP)

(73) Assignee: FUSO CHEMICAL CO., LTD., Osaka-shi, Osaka (JP)

(21) Appl. No.: 18/722,801

(22) PCT Filed: Dec. 23, 2021
(86) PCT No.: PCT/JP2021/047846

§ 371 Date: Jun. 21, 2024

(51) Int. Cl. C01B 33/141; C01B 33/145; C09G 1/02; C09K 3/14

(52) U.S. Cl. CPC C01B 33/141; C01B 33/145; C09G 1/02; C09K 3/1409; C01P 2004/64; C01P 2006/80

(57) ABSTRACT

A colloidal silica comprising water and silica particles, wherein the specific relaxation rate, as measured by pulsed NMR at a silica particle concentration of 3 mass %, is 0.60 or more, and the zeta potential of the surface of the silica particles in the pH range of 2 to 5 is −10 to 10 mV.

### TECHNICAL FIELD

The present invention relates to colloidal silica and a method for producing the colloidal silica.

### BACKGROUND ART

With the miniaturization of semiconductor line widths, the importance of a high level of flatness, a low level of defectiveness, and a low level of metal contamination is increasing in chemical mechanical polishing processes. Given this, silica particles with a small particle size, good dispersion stability, and a low concentration of metal impurities are in demand.

Patent Literature (PTL) 1 and 2 describe silica sol particles with a small particle size of the silica particles and excellent dispersion stability of the particles.

Silica particles typically exhibit good dispersion stability under basic conditions. Under acidic conditions, however, the zeta potential approaches 0 mV; thus, maintaining dispersion stability is difficult, and particle aggregation easily occurs.

However, the silica particles disclosed in PTL 1 and 2 do not provide sufficient dispersion stability under acidic conditions although adjusting the pH of a polishing composition to an acidic value is necessary in some chemical mechanical polishing processes. Accordingly, silica particles with excellent dispersion stability even under acidic conditions are in demand.

PTL 3 and PTL 4 disclose a method for modifying the surface of silica particles with a modifier as a method for obtaining excellent dispersion stability of silica particles under acidic conditions.

However, in the methods disclosed in PTL 3 and PTL 4, the particles have a strong positive or negative charge in the acidic region. Thus, a strong electrostatic repulsion occurs between the particles and a polished object with the same charge while a strong electrostatic attraction occurs between the particles and a polished object with the opposite charge. Under the conditions in which a strong electrostatic repulsion occurs, as disclosed in Non-patent Literature (NPL) 1, the particles become less likely to approach the polished object, resulting in a decrease in the polishing removal rate. Under the conditions in which a strong electrostatic attraction occurs, adhesion of particles to the polished object is promoted; however, if adhesion is excessively promoted, removing the particles from the polished object becomes difficult. In particular, as disclosed in NPL 2, as the miniaturization of semiconductor line widths progresses, there is a tendency that particle adhesion to a polished object becomes problematic. Therefore, it is difficult to apply particles with too strong adhesion properties in advanced semiconductor manufacturing processes, in which miniaturization is progressing. For this reason, the silica particles above have limited targets for polishing.

Accordingly, there is a demand for silica particles that have excellent dispersion stability even under acidic conditions and that can be used for a wide range of objects for polishing.

### CITATION LIST

### Patent Literature

PTL 1: JP4011566B
PTL 2: JP2004-315300A
PTL 3: JP2010-269985A
PTL 4: JP2005-162533A

### Non-Patent Literature

NPL 1: Journal of the Japan Society of Advanced Production Technology, Vol. 29, No. 1, 2011.1, Analysis of Polishing Friction Factor for Material Removal Rate Improvement in CMP
NPL 2: Aerosol Science and Technology (1987), Vol. 7, pp. 161-176

### SUMMARY OF INVENTION

### Technical Problem

In view of the above circumstances, an object of the present invention is to provide colloidal silica with excellent dispersion stability even under acidic conditions, without using a modifier.

### Solution to Problem

As a result of extensive research to solve the above problem, the present inventors have found that the dispersion stability of colloidal silica under acidic conditions can be improved by adjusting the specific relaxation rate in the colloidal silica to be equal to or more than a specific value. The present inventors have further conducted research based on the above findings and completed the present invention.

More specifically, the present invention provides the following colloidal silica and method for producing the colloidal silica.

### Item 1.

A colloidal silica comprising water and silica particles,
wherein
the specific relaxation rate, as measured by pulsed MAR at a silica particle concentration of 3 mass %, is 0.60 or more, and
the zeta potential of the surface of the silica particles in the pH range of 2 to 5 is −10 to 10 mV.

### Item 2.

The colloidal silica according to Item 1, wherein the silica particles have an average particle size, as measured by a dynamic light scattering method, of 30 nm or less.

### Item 3.

The colloidal silica according to Item 1 or 2, wherein the colloidal silica has a metal impurity content of 1 ppm or less.

### Item 4.

The colloidal silica according to any one of Items 1 to 3, wherein the increase rate of the average particle size after adjustment of pH to 4.6 by adding hydrochloric acid and storage for 48 hours at 25° C. is 10% or less.

### Item 5.

A polishing composition comprising the colloidal silica of any one of Items 1 to 4.

### Item 6.

A method for producing the colloidal silica of any one of Items 1 to 4, comprising
injecting an alkoxysilane into a mother liquor containing an organic solvent, an alkaline catalyst, and water under the following reaction conditions (1) to (4):
(1) reaction temperature: 21 to 50° C.;
(2) alkaline catalyst content in the mother liquor: 0.10 to 1.00 mol per liter of a reaction liquid obtained by injecting the alkoxysilane into the mother liquor;
(3) water content in the mother liquor: 4 mol or more per mole of the injection amount of the alkoxysilane; and
(4) injection rate of the alkoxysilane: 3.00 mL/min or less per liter of the reaction liquid.

### Advantageous Effects of Invention

The colloidal silica according to the present invention described above has excellent dispersion stability under acidic conditions, even though a modifier is not used.

### BRIEF DESCRIPTION OF DRAWINGS

FIG. 1 shows the results of zeta potential measurements of the Examples and Comparative Examples.

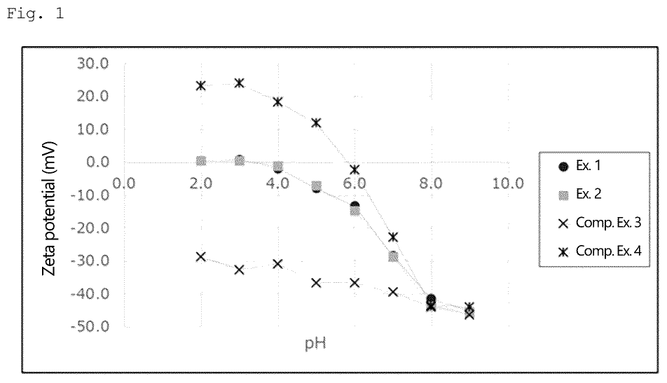

### DESCRIPTION OF EMBODIMENTS

### 1. Colloidal Silica

The colloidal silica of the present invention comprises water and silica particles. The colloidal silica of the present invention may also comprise substances other than water and silica particles as long as the effect and purpose are not impaired. It is also a preferable embodiment that the colloidal silica of the present invention consists of water and silica particles.

In the colloidal silica of the present invention, the specific relaxation rate, as measured by pulsed NMR at a silica particle concentration of 3 mass %, is 0.60 or more, preferably 0.65 or more, more preferably 0.70 or more, and even more preferably 0.75 or more. If the specific relaxation rate, as measured by pulsed NMR at a silica particle concentration of 3 mass %, is less than 0.60, the dispersion stability under acidic conditions becomes poor.

In the colloidal silica of the present invention, the upper limit of the specific relaxation rate, as measured by pulsed NMR at a silica particle concentration of 3 mass %, is not particularly limited and is, for example, 10.00.

In the present specification, the specific relaxation rate, as measured by pulsed NMR at a silica particle concentration of 3 mass %, is defined to be measured and calculated as follows.

First, a measurement sample is obtained by adding ultrapure water to colloidal silica to adjust the silica particle concentration to 3 mass %. By using the obtained measurement sample and by using a pulsed NMR particle surface area analyzer (e.g., Acorn Area, produced by Xigo Nanotools), a CPMG method in which signals are collected by changing the phase of pulses according to a spin-echo method is performed by setting time intervals between 90° pulse application and 180° pulse application to 0.5 ms to measure transverse relaxation time T2 (“T2 of colloidal silica” in the formula below), which indicates the attenuation rate. Additionally, the same operation is performed by using ultrapure water as the measurement sample to obtain transverse relaxation time T2 (“T2 of ultrapure water” in the formula below). The specific relaxation rate is calculated from the obtained T2 values according to the following formula.

$$Specific relaxation rate = \{ ( 1 / T 2 of colloidal silica ) / ( 1 / T 2 of ultrapure water ) \} - 1$$

In the colloidal silica, the zeta potential of the surface of the silica particles in the pH range of 2 to 5 is −10 mV or more, preferably −9 mV or more, and more preferably −8 mV or more. Similarly, the zeta potential of the surface of the silica particles is 10 mV or less, preferably 9 mV or less, and more preferably 8 mV or less. By adopting such a configuration, electrostatic repulsion between the particles and a polished object having the same charge is suppressed, and the polishing removal rate improves. In addition, electrostatic attraction between the particles and a polished object having the opposite charge is reduced, and the adhesion of the particles to the polished object is suppressed.

In the present specification, the zeta potential of silica particles is defined to be measured as follows.

The measurement sample is a diluted liquid obtained by adjusting the concentration of the silica particles in the colloidal silica to 1 mass % by using a 10 mM sodium chloride aqueous solution. The pH of the obtained measurement sample is adjusted with a 0.1 M sodium hydroxide aqueous solution and 0.1 M hydrochloric acid, and the zeta potential at each pH value, i.e., 9, 8, 7, 6, 5, 4, 3, and 2, is measured with an ELS-Z, produced by Otsuka Electronics Co., Ltd.

The average particle size of the silica particles contained in the colloidal silica is preferably 3 nm or more, more preferably 5 nm or more, and even more preferably 7 nm or more, in order to obtain a higher polishing rate. Further, the average particle size of the silica particles is preferably 30 nm or less, more preferably 27 nm or less, and even more preferably 25 nm or less, in order to reduce the risk of the occurrence of scratches on the surface of the polished object.

The average particle size of the silica particles can be measured and calculated according to common methods, without particular limitation. For example, dynamic light scattering may be used for the measurement.

The BET specific surface area of the silica particles contained in the colloidal silica is preferably 100 m²/g or more, more preferably 115 m²/g or more, and even more preferably 130 m²/g or more. The BET specific surface area of the silica particles is preferably 1000 m²/g or less, more preferably 600 m²/g or less, and even more preferably 400 m²/g or less.

In the present specification, the BET specific surface area of silica particles is defined to be measured by using a sample obtained by pre-drying colloidal silica on a hot plate, followed by heating at 800° C. for 1 hour.

As described above, the colloidal silica of the present invention comprises water and silica particles. However, it is also preferable that the colloidal silica comprises an organic solvent as a dispersion medium for the silica particles, in addition to water.

The organic solvents are usually hydrophilic organic solvents. Examples include alcohols (e.g., methanol, ethanol, n-propanol, isopropanol, ethylene glycol, propylene glycol, and 1,4-butanediol), ketones (e.g., acetone and methyl ethyl ketone), and esters (e.g., ethyl acetate). These organic solvents may be used alone or in a combination of two or more.

The content of the silica particles in the colloidal silica is preferably 3 mass % or more, more preferably 4 mass % or more, even more preferably 5 mass % or more, and still more preferably 6 mass % or more, for the reason that the amounts of additives for blending are easily adjusted when the colloidal silica is used as a starting material of a polishing composition.

### 2. Polishing Composition

The present invention encompasses an invention relating to a polishing composition comprising the colloidal silica described above. The polishing composition can be suitably used for chemical mechanical polishing.

The polishing composition of the present invention may further comprise additives without particular limitation, as long as the polishing composition comprises the colloidal silica of the present invention described above. Examples of additives include diluents, oxidants, pH adjusters, corrosion inhibitors, stabilizers, and surfactants. These may be used alone or in a combination of two or more.

The content of the silica particles in the polishing composition is, for example, 0.01 to 20 mass %, more preferably 0.05 to 10 mass %, and even more preferably 0.1 to 5 mass %.

### 3. Method for Producing Colloidal Silica

The present invention encompasses an invention relating to a method for producing the colloidal silica described above.

The method for producing the colloidal silica of the present invention comprises the step of injecting an alkoxysilane into a mother liquor containing an organic solvent, an alkaline catalyst, and water (also referred to below as “step 1”).

### 3.1. Step 1

Step 1 is carried out under the following reaction conditions (1) to (4):
(1) reaction temperature: 21 to 50° C.;
(2) alkaline catalyst content in the mother liquor: 0.10 to 1.00 mol per liter of a reaction liquid obtained by injecting the alkoxysilane into the mother liquor;
(3) water content in the mother liquor: 4 mol or more per mole of the injection amount of the alkoxysilane; and
(4) injection rate of the alkoxysilane: 3.00 mL/min or less per 5 liter of the reaction liquid.

The organic solvents are usually hydrophilic organic solvents. Examples include alcohols (e.g., methanol, ethanol, n-propanol, isopropanol, ethylene glycol, propylene glycol, and 1,4-butanediol), ketones (e.g., acetone and methyl ethyl ketone), and esters (e.g., ethyl acetate). These organic solvents may be used alone or in a combination of two or more.

The type of the alkaline catalyst is not particularly limited. To avoid metal impurity contamination, the alkaline catalyst is preferably an organic base catalyst that does not contain a metal component, and particularly preferably a nitrogen-containing organic base catalyst. Examples of such organic base catalysts include ethylenediamine, diethylenetriamine, triethylenetetramine, ammonia, urea, monoethanol amine, diethanol amine, triethanol amine, tetramethylammonium hydroxide (TMAH), tetramethylguanidine, 3-ethoxypropylamine, dipropylamine, and triethylamine. These may be used alone or in a combination of two or more. Ammonia, which has excellent catalytic activity and high volatility, and which can be easily removed in a subsequent step, is preferred. From the standpoint of increasing the density of silica particles, it is preferable to select an organic base catalyst with a boiling point of 90° C. or higher so as to avoid volatilization even when the reaction temperature is increased, and it is more preferable to use at least one member selected from tetramethylammonium hydroxide and 3-ethoxypropylamine.

The content of the alkaline catalyst in the mother liquor is 0.10 mol or more, preferably 0.12 mol or more, and more preferably 0.14 mol or more, per liter of a reaction liquid obtained by injecting the alkoxysilane into the mother liquor. If the alkaline catalyst content is less than 0.10 mol per liter of the reaction liquid, the synthesized particles form aggregates; thus a nanoparticle dispersion cannot be obtained.

The content of the alkaline catalyst in the mother liquor is 1.00 mol or less, preferably 0.80 mol or less, and more preferably 0.60 mol or less, per liter of the above reaction liquid. If the alkaline catalyst content exceeds 1.00 mol per liter of the above reaction liquid, the condensation of nuclear particles is accelerated, and the particle size increases; consequently, a nanoparticle dispersion cannot be obtained.

The content of water in the mother liquor is 4 mol or more, preferably 5 mol or more, and more preferably 6 mol or more, per mole of the injection amount of the alkoxysilane. If the water content in the mother liquor is less than 4 mol per mole of the injection amount of the alkoxysilane, the hydrolysis of the alkoxysilane does not proceed sufficiently, and spherical particles cannot be obtained.

The upper limit of the water content in the mother liquor is not particularly limited. The upper limit is preferably 30 mol per mole of the injection amount of the alkoxysilane.

Examples of alkoxysilanes include tetra-C₁₋₈ alkoxysilanes, such as tetramethoxysilane, tetraethoxysilane, and tetraisopropoxysilane. These may be used alone or in a combination of two or more. Of these, tetra-C₁₋₄ alkoxysilanes are preferred, and tetramethoxysilane and/or tetraethoxysilane are even more preferred.

The injection rate of the alkoxysilane in step 1 is 3.00 mL/min or less, preferably 2.97 mL/min or less, and more preferably 2.95 mL/min or less, per liter of the reaction liquid. If the injection rate of the alkoxysilane exceeds 3.00 mL/min per liter of the reaction liquid, the synthesized particles form aggregates; thus a nanoparticle dispersion cannot be obtained.

The lower limit of the injection rate of the alkoxysilane in step 1 is not particularly limited and is preferably, for example, 0.01 mL/min or more per liter of the reaction liquid.

The alkoxysilane is preferably injected after being dissolved in an appropriate solvent. The solvent for the alkoxysilane is a hydrophilic organic solvent, like those mentioned above for use in the mother liquor. Examples include alcohols (e.g., methanol, ethanol, n-propanol, isopropanol, ethylene glycol, propylene glycol, and 1,4-butanediol), ketones (e.g., acetone and methyl ethyl ketone), and esters (e.g., ethyl acetate). These organic solvents may be used alone or in a combination of two or more. The organic solvent for use here may be the same organic solvent used for the mother liquor or may be a different organic solvent.

The alkoxysilane concentration in the alkoxysilane solution is preferably 1 mol/L or more, and more preferably 2 mol/L or more. Similarly, the alkoxysilane concentration is preferably 6 mol/L or less, and more preferably 5 mol/L or less. An alkoxysilane concentration of 2 mol/L or more increases the productivity of silica particles. An alkoxysilane concentration of 5 mol/L or less suppresses the occurrence of particle aggregation.

The reaction temperature in step 1 is 21° C. or higher, preferably 22° C. or higher, and more preferably 23° C. or higher. If the reaction temperature is lower than 21° C., the synthesized particles have a deformed shape, resulting in reduced dispersion stability of the particles.

The reaction temperature in step 1 is 50° C. or lower, preferably 45° C. or lower, and more preferably 40° C. or lower. If the reaction temperature is set higher than 50° C., the specific relaxation rate of the synthesized particles decreases, resulting in reduced dispersion stability of the particles.

### 3.2. Step 2

It is also preferable that the method for producing the colloidal silica of the present invention further comprises the step of replacing the liquid component in the reaction liquid obtained in step 1 with water (also referred to simply as “step 2”).

In step 2, known methods for replacement used in the related technical fields can be widely used, without particular limitation. Examples include a method in which water is added after distilling off of the reaction liquid obtained in step 1.

The embodiments of the present invention are described above. However, the present invention is not limited to these examples and can of course be implemented in various forms within the scope that does not deviate from the spirit of the present invention.

### EXAMPLES

The embodiments of the present invention will be described in more detail below with reference to Examples; however, the present invention is not limited to these Examples.

### Example 1

A mother liquor was prepared by mixing 100 parts by mass of methanol, 41 parts by mass of ultrapure water, and 6 parts by mass of 28 mass % aqueous ammonia. A starting material solution was prepared by mixing 15 parts by mass of methanol and 28 parts by mass of tetramethoxysilane, relative to 100 parts by mass of the methanol used for the mother liquor. While maintaining the temperature of the mother liquor at 35° C., the starting material solution was injected into the mother liquor at a constant rate for 300 minutes to obtain a reaction liquid. The ammonia content in the mother liquor was 0.45 mol per liter of the reaction liquid. The water content in the mother liquor was 14 mol per mole of the injected tetramethoxysilane. The injection rate into the mother liquor in terms of pure tetramethoxysilane was 0.41 mL/min per liter of the reaction liquid. While distilling off the solvent by heating, ultrapure water in an amount of 190 parts by mass relative to 100 parts by mass of the obtained reaction liquid was fed to completely replace the solvent components with water while maintaining a constant volume, whereby colloidal silica was obtained.

### Example 2

A mother liquor was prepared by mixing 100 parts by mass of methanol, 16 parts by mass of ultrapure water, and 3 parts by mass of 28 mass % aqueous ammonia. A starting material solution was prepared by mixing 6 parts by mass of methanol and 23 parts by mass of tetramethoxysilane, relative to 100 parts by mass of the methanol used for the mother liquor. While maintaining the temperature of the mother liquor at 22° C., the starting material solution was injected into the mother liquor at a constant rate for 43 minutes to obtain a reaction liquid. The ammonia content in the mother liquor was 0.25 mol per liter of the reaction liquid. The water content in the mother liquor was 7 mol per mole of the injected tetramethoxysilane. The injection rate into the mother liquor in terms of pure tetramethoxysilane was 2.91 mL/min per liter of the reaction liquid. While distilling off the solvent by heating, ultrapure water in an amount of 190 parts by mass relative to 100 parts by mass of the obtained reaction liquid was fed to completely replace the solvent components with water while maintaining a constant volume, whereby colloidal silica was obtained.

### Comparative Example 1

A mother liquor was prepared by mixing 100 parts by mass of methanol, 5 parts by mass of ultrapure water, and 1 part by mass of 28 mass % aqueous ammonia. A starting material solution was prepared by mixing 6 parts by mass of methanol and 12 parts by mass of tetramethoxysilane, relative to 100 parts by mass of the methanol used for the mother liquor. While maintaining the temperature of the mother liquor at 60° C., the starting material solution was injected into the mother liquor at a constant rate for 127 minutes to obtain a reaction liquid. The ammonia content in the mother liquor was 0.11 mol per liter of the reaction liquid. The water content in the mother liquor was 4 mol per mole of the injected tetramethoxysilane. The injection rate into the mother liquor in terms of pure tetramethoxysilane was 0.62 mL/min per liter of the reaction liquid. While distilling off the solvent by heating, ultrapure water in an amount of 190 parts by mass relative to 100 parts by mass of the obtained reaction liquid was fed to completely replace the solvent components with water while maintaining a constant volume, whereby colloidal silica was obtained.

### Comparative Example 2

A mother liquor was prepared by mixing 100 parts by mass of methanol, 16 parts by mass of ultrapure water, and 3 parts by mass of 28 mass % aqueous ammonia. A starting material solution was prepared by mixing 3 parts by mass of methanol and 12 parts by mass of tetramethoxysilane, relative to 100 parts by mass of the methanol used for the mother liquor. While maintaining the temperature of the mother liquor at 20° C., the starting material solution was injected into the mother liquor at a constant rate for 30 minutes to obtain a reaction liquid. The ammonia content in the mother liquor was 0.26 mol per liter of the reaction liquid. The water content in the mother liquor was 12 mol per mole of the injected tetramethoxysilane. The injection rate into the mother liquor in terms of pure tetramethoxysilane was 2.50 mL/min per liter of the reaction liquid. While distilling off the solvent by heating, ultrapure water in an amount of 190 parts by mass relative to 100 parts by mass of the obtained reaction liquid was fed to completely replace the solvent components with water while maintaining a constant volume, whereby colloidal silica was obtained.

### Comparative Example 3

A mother liquor was prepared by mixing 100 parts by mass of methanol, 6 parts by mass of ultrapure water, and 6 parts by mass of 26 mass % aqueous ammonia. A starting material solution was prepared by mixing 3 parts by mass of methanol and 12 parts by mass of tetramethoxysilane, relative to 100 parts by mass of the methanol used for the mother liquor. While maintaining the temperature of the mother liquor at 35° C., the starting material solution was injected into the mother liquor at a constant rate for 55 minutes to obtain a reaction liquid. The ammonia content in the mother liquor was 0.67 mol per liter of the reaction liquid. The water content in the mother liquor was 8 mol per mole of the injected tetramethoxysilane. The injection rate into the mother liquor in terms of pure tetramethoxysilane was 1.34 mL/min per liter of the reaction liquid. The entire amount of the obtained reaction liquid was heated and concentrated under ordinary pressure to obtain 35 parts by mass of a concentrated liquid. Then, 0.046 parts by mass of 3-mercaptopropyltrimethoxysilane was added to the concentrated liquid, and the mixture was refluxed at a boiling point for 1 hour for thermal aging. Subsequently, while distilling off the solvent by heating, ultrapure water was fed to replace the solvent components with water while maintaining a constant volume, and the replacement of the solvent components with water was terminated when the pH was 8 or less. After the liquid obtained after replacement with water was cooled to room temperature, 0.483 parts by mass of a 30% aqueous solution of hydrogen peroxide was added thereto, and the mixture was heated to reflux for 8 hours, whereby sulfo group-modified colloidal silica was obtained.

### Comparative Example 4

A mother liquor was prepared by mixing 100 parts by mass of methanol, 6 parts by mass of ultrapure water, and 6 parts by mass of 26 mass % aqueous ammonia. A starting material solution was prepared by mixing 3 parts by mass of methanol and 12 parts by mass of tetramethoxysilane, relative to 100 parts by mass of the methanol used for the mother liquor. While maintaining the temperature of the mother liquor at 35° C., the starting material solution was injected into the mother liquor at a constant rate for 55 minutes to obtain a reaction liquid. The ammonia content in the mother liquor was 0.67 mol per liter of the reaction liquid. The water content in the mother liquor was 8 mol per mole of the injected tetramethoxysilane. The injection rate into the mother liquor in terms of pure tetramethoxysilane was 1.34 mL/min per liter of the reaction liquid. The entire amount of the obtained reaction liquid was heated and concentrated under ordinary pressure to obtain 22 parts by mass of a concentrated liquid. Subsequently, while distilling off the solvent by heating, ultrapure water was fed to replace the solvent components with water while maintaining a constant volume, and the replacement of the solvent components with water was terminated when the pH was 8 or less. A liquid mixture of 0.012 parts by mass of 3-aminopropyltrimethoxysilane and 0.231 parts by mass of methanol was injected for 10 minutes into 7 parts by mass of the liquid obtained after replacement with water, and the resulting mixture was heated to reflux for 2 hours under ordinary pressure. Subsequently, while distilling off the solvent by heating, ultrapure water was fed to replace the solvent components with water while maintaining a constant volume, and when the temperature of the distilled liquid reached 100° C., the replacement with water was terminated, whereby amino group-modified colloidal silica was obtained.

### Measurement of Specific Relaxation Rate

The relaxation time of colloidal silica and a dispersion medium thereof was measured by using a pulsed NMR particle surface area analyzer (Acorn Area, produced by Xigo Nanotools). Ultrapure water was added to the colloidal silica to adjust the silica concentration to 3 mass % to obtain measurement samples. A CPMG method in which signals are collected by changing the phase of pulses according to a spin-echo method was performed by setting time intervals between 90° pulse application and 180° pulse application to 0.5 ms to measure transverse relaxation time T2, which indicates the attenuation rate. From the obtained T2 values, the specific relaxation rate was calculated according to the following formula.

$$Specific relaxation rate = \{ ( 1 / T 2 of colloidal silica ) / ( 1 / T 2 of ultrapure water ) \} - 1$$

### Measurement of Average Particle Size

The colloidal silica was diluted by adding a 0.3 mass % citric acid aqueous solution to a silica concentration of 0.3 mass %. The diluted liquids were used as measurement samples. By using the measurement samples, the average particle size was measured by a dynamic light scattering method (ELSZ-20005, produced by Otsuka Electronics Co., Ltd.).

### Measurement of Metal Impurity Content

Inductively coupled plasma mass spectrometry (ICP-MS) was used to measure the metal impurity content in the colloidal silica.

### Measurement of Zeta Potential

The colloidal silica of Example 1, Example 2, Comparative Example 3, and Comparative Example 4 was individually diluted with a 10 mM sodium chloride aqueous solution so that the silica particle concentration was 1 mass % to obtain diluted liquids, and the obtained diluted liquids were used as measurement samples. The pH of the obtained measurement samples was adjusted with a 0.1 M sodium hydroxide aqueous solution and a 0.1 M hydrochloric acid, and the zeta potential at each pH value, i.e., 9, 8, 7, 6, 5, 4, 3, and 2, was measured with an ELS-Z, produced by Otsuka Electronics Co., Ltd.

Evaluation Test for Dispersion Stability under Acidic Conditions

Ultrapure water and 1 mol/L hydrochloric acid were added to the colloidal silica of the Examples and Comparative Examples to adjust the silica concentration to 3 mass % and the pH to 4.6. The obtained specimens were each placed in a fluororesin container, and the containers were sealed, followed by storing at 25° C. for 48 hours. The average particle sizes before and after storage were measured, and the increase rate of the average particle size was calculated according to the following formula. A higher value of the increase rate of the average particle size indicates that the aggregation of silica particles proceeded, and that the dispersion stability was poor. Conversely, a lower value of the increase rate of the average particle size indicates that the dispersion stability of the silica particles was good.

$$Increase rate of average particle size ( \% ) = ( average particle size after storage - average particle size before storage ) \times 100 / ( average particle size before storage )$$

As shown in Table 1 below, the Comparative Examples showed a difference in the average particle size between before and after 48 hours of storage, whereas the Examples showed almost no difference in the average particle size between before and after 48 hours of storage.

TABLE 1

| | | | | | Comparative Example | | | |
|---|---|---|---|---|---|---|---|---|
| | | | Example | | Comp. | Comp. | Comp. | Comp. |
| Item | | | Ex. 1 | Ex. 2 | Ex. 1 | Ex. 2 | Ex. 3 | Ex. 4 |
| Production | Mother | Ammonia content, mol | 0.45 | 0.25 | 0.11 | 0.26 | 0.67 | 0.67 |
| method | liquor | (per liter of reaction liquid) | | | | | | |
| | | Water content, mol | 14 | 7 | 4 | 12 | 8 | 8 |
| | | (per mole of injection amount | | | | | | |
| | | of tetramethoxysilane) | | | | | | |
| | Starting | Injection rate of | 0.41 | 2.91 | 0.62 | 2.50 | 1.34 | 1.34 |
| | material | tetramethoxysilane, mL/min | | | | | | |
| | solution | (per liter of reaction liquid) | | | | | | |

| | | | | | | | |
|---|---|---|---|---|---|---|---|
| | Reaction temperature, ° C. | 35 | 22 | 60 | 20 | 35 | 35 |
| Physical | Particle size, nm | 11.4 | 21.3 | 9.2 | 38.0 | 29.9 | 37.4 |
| properties | (measured by DLS) | | | | | | |
| | Specific relaxation rate | 0.78 | 0.80 | 0.53 | 0.58 | 1.62 | 1.51 |
| | Particle size (pH: 4.6), nm | 11.5 | 21.4 | 9.3 | 38.3 | — | — |
| | Particle size after 48 | 11.6 | 21.3 | 11.7 | 42.5 | — | — |
| | hours (pH 4.6), nm | | | | | | |
| | Increase rate of particle size | 1 | 0 | 26 | 11 | — | — |
| | after 48 hours (pH: 4.6), % | | | | | | |

1. A colloidal silica comprising water and silica particles,
wherein
the specific relaxation rate, as measured by pulsed NMR at a silica particle concentration of 3 mass %, is 0.60 or more, and
the zeta potential of the surface of the silica particles in the pH range of 2 to 5 is −10 to 10 mV.

2. The colloidal silica according to claim 1, wherein the silica particles have an average particle size, as measured by a dynamic light scattering method, of 30 nm or less.

3. The colloidal silica according to claim 1, wherein the colloidal silica has a metal impurity content of 1 ppm or less.

4. The colloidal silica according to claim 1, wherein the increase rate of the average particle size after adjustment of pH to 4.6 by adding hydrochloric acid and storage for 48 hours at 25° C. is 10% or less.

5. A polishing composition comprising the colloidal silica of claim 1.

6. A method for producing the colloidal silica of claim 1, comprising
injecting an alkoxysilane into a mother liquor containing an organic solvent, an alkaline catalyst, and water under the following reaction conditions (1) to (4):
(1) reaction temperature: 21 to 50° C.;
(2) alkaline catalyst content in the mother liquor: 0.10 to 1.00 mol per liter of a reaction liquid obtained by injecting the alkoxysilane into the mother liquor;
(3) water content in the mother liquor: 4 mol or more per mole of the injection amount of the alkoxysilane; and
(4) injection rate of the alkoxysilane: 3.00 mL/min or less per liter of the reaction liquid.
